(19) United States
(12) Patent Application Publication
(10) Pub. No.: US 2026/0211061 A1
(43) Pub. Date: Jul. 23, 2026

(54) HIGH-BANDWIDTH MULTIPATH HALL SENSOR

(71) Applicant: Allegro MicroSystems, LLC, Manchester, NH (US)

(72) Inventor: Hernán D. Romero, Buenos Aires (AR)

(73) Assignee: Allegro MicroSystems, LLC, Manchester, NH (US)

(21) Appl. No.: 19/034,776

(22) Filed: Jan. 23, 2025

(51) Int. Cl. G01R 33/07

(52) U.S. Cl. CPC G01R 33/075; G01R 33/077

(57) ABSTRACT

A sensor, comprising: a first signal path including one or more first Hall elements that are configured to generate a first signal in response to an external magnetic field that is incident on the sensor and a reference magnetic field, the first signal path being configured to process the first signal to generate a first processed signal; a second signal path including one or more second Hall elements that are configured to generate a second signal in response to the external magnetic field and the reference magnetic field, the second signal path being configured to process the second signal to generate a second processed signal; a feedback coil that is configured to generate the reference magnetic field; and a feedback circuit that is configured to use the use the first processed signal to adjust respective biases of the first Hall elements and the second Hall elements.

### BACKGROUND

As is known, sensors are used to perform various functions in a variety of applications. Some sensors include one or more electromagnetic flux sensing elements, such as a Hall effect element, a magnetoresistive element, or a receiving coil to sense an electromagnetic flux associated with a quantity that is desired to be monitored. Sensor integrated circuits are widely used in automobile control systems and other safety-critical applications. There are a variety of specifications that set forth requirements related to permissible sensor quality levels, failure rates, and overall functional safety.

### SUMMARY

According to aspects of the disclosure, a sensor is provided, comprising: a first signal path including one or more first Hall elements that are configured to generate a first signal in response to an external magnetic field that is incident on the sensor and a reference magnetic field, the first signal path further including a first electronic circuitry that is configured to process the first signal to generate a first processed signal; a second signal path including one or more second Hall elements that are configured to generate a second signal in response to the external magnetic field and the reference magnetic field, the second signal path further including a second electronic circuitry that is configured to process the second signal to generate a second processed signal; a feedback coil that is configured to generate the reference magnetic field, the reference magnetic field having a reference magnetic field frequency. a feedback circuit that is configured to: receive the first signal, demodulate the first signal at the reference magnetic field frequency to generate a demodulated signal, integrate the demodulated signal to produce an integrated signal, and use the integrated signal to adjust respective biases of the first Hall elements and the second Hall elements; and a combination circuit that is configured to combine the first signal and the second signal to produce an output signal, the output signal being generated at least in part based on the first signal and the second signal.

According to aspects of the disclosure, a sensor is provided, comprising: a first signal path including one or more first Hall elements that are configured to generate a first signal in response to an external magnetic field that is incident on the sensor and a reference magnetic field, the first signal path further including a first electronic circuitry that is configured to process the first signal to generate a first processed signal; a second signal path including one or more second Hall elements that are configured to generate a second signal in response to the external magnetic field and the reference magnetic field, the second signal path further including a second electronic circuitry that is configured to process the second signal to generate a second processed signal; a summation element configured to add the first processed signal to the second processed signal to generate an output signal of the sensor; and a feedback circuit including an integrator, a feedback coil configured to generate the reference magnetic field, a feedback coil driver, and an integrator, the integrator being configured to integrate the output signal to generate an integrated signal, the feedback coil driver being configured to drive the feedback coil with a drive current that is generated at least in part based on the integrated signal.

### BRIEF DESCRIPTION OF THE DRAWINGS

The foregoing features may be more fully understood from the following description of the drawings in which:

FIG. 1A is a diagram of an example of a sensor, according to aspects of the disclosure;

FIG. 1B is a diagram illustrating aspects of the operation of the sensor of FIG. 1A, according to aspects of the disclosure;

FIG. 1C is a diagram illustrating aspects of the operation of the sensor of FIG. 1A, according to aspects of the disclosure;

FIG. 1D is a diagram illustrating aspects of the operation of the sensor of FIG. 1A, according to aspects of the disclosure;

FIG. 1E is a diagram illustrating aspects of the operation of the sensor of FIG. 1A, according to aspects of the disclosure;

FIG. 2 is a diagram of an example of a sensor, according to aspects of the disclosure; and

FIG. 3 is a schematic diagram of a sensor, according to aspects of the disclosure.

### DETAILED DESCRIPTION

Typically, Hall sensors with high accuracy are bandwidth-limited. The limitation in bandwidth results from the use of offset compensation techniques required to increase overall accuracy. Frequency chopping is an example of one such technique, which is both well-known and widely-spread. Frequency chopping allows the Hall plate offset component to be modulated to high frequencies, after which the Hall plate offset is filtered out by a low-pass filter provided down the signal chain. The speed at which a Hall plate can be spun without creating dynamic residual offset components is limited to a few hundred KHz at the most. The speed limitation is related to the inherent time constants of Hall plates. Therefore, achieving high offset performance and very high bandwidth (higher than say 500 KHz to 1 MHz) is practically impossible, in at least some applications.

The present disclosure provides a sensor that implements a dual-path solution. The sensor includes two sensing paths that use Hall elements to sense magnetic fields. One of the paths is intended to provide accuracy at low frequencies (including DC), and it uses frequency chopping to remove any offset present in the output of this path's respective Hall elements. The other path is intended to provide high accuracy at a high frequency, and it does not use frequency chopping, which as noted above degrades the sensor accuracy if chopping frequency is too high. The former sensing path is herein referred to as “the low-frequency path of the sensor” and the latter sensing path is herein referred to as “the high-frequency path of the sensor”.

The dual-path solution that is disclosed herein is a “homogenous solution”. This is because both signal paths utilize the same type of sensing elements—i.e., they both utilize Hall elements. The homogeneity is advantageous because it permits errors related to, for example, sensitivity stability over environmental conditions (such as temperature, mechanical stresses, and stray field) to be tackled in the same way, and simultaneously, on both signal paths. In general, this would not be possible if the two paths used different types of sensing elements.

The dual-path solution that is disclosed herein achieves sufficient offset stability. This is because the low-frequency path uses frequency chopping, which would effectively remove any offset present in the signal generated by the low-frequency path.

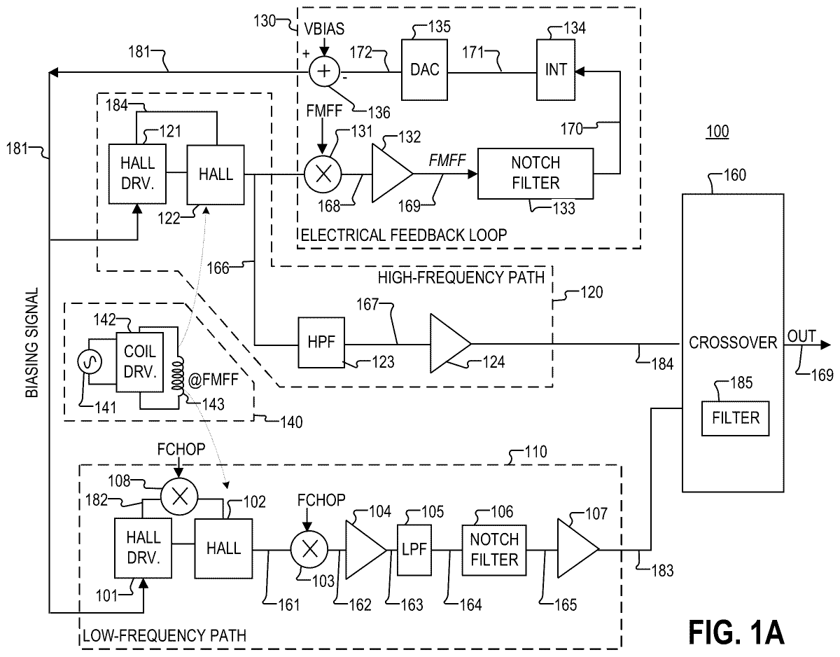

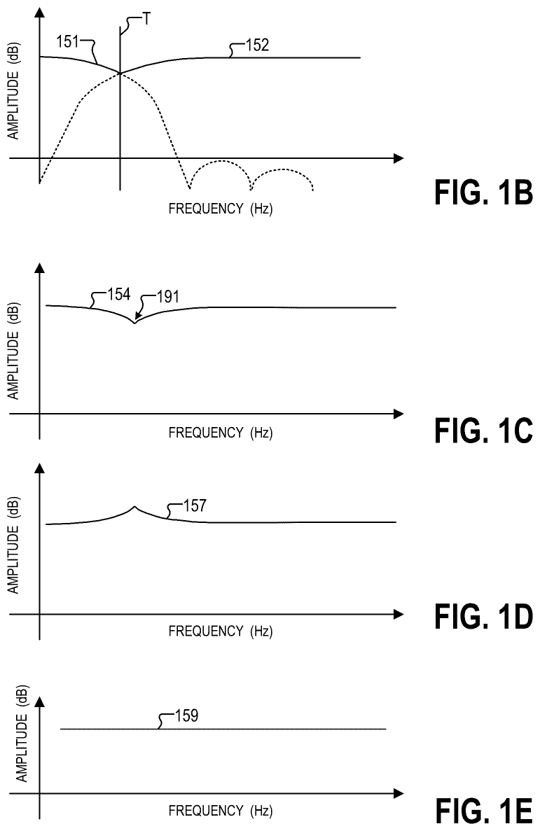

FIG. 1A is a diagram of a magnetic field sensor 100, according to aspects of the disclosure. Sensor 100 may include a position sensor, a current sensor, a speed sensor, and/or any other suitable type of magnetic field sensor.

According to the present disclosure, sensor 100 includes a low-frequency signal path 110 (hereinafter “signal path 110”), a high-frequency signal path 120 (hereinafter “signal path 120”), an electrical feedback loop 130 (hereinafter “feedback loop 130”), a feedback generator 140, and a crossover circuit 160 (hereinafter “crossover 140”). Signal path 110 may include a driver circuit 101, one or more Hall elements 102, a modulator 108, a demodulator 103, an amplifier 104, a low-pass filter (LPF) 105, a notch filter 106, and an amplifier 107. Signal path 120 may include a driver circuit 121, one or more Hall elements 122, a high-pass filter (HPF) 123, and an amplifier 124. According to the present example, Hall elements 102 and 122 include planar Hall elements. However, alternative implementations are possible in which any of Hall elements 102 and 122 includes one or more vertical Hall elements and/or any other suitable type of Hall element. The HPF 123 may be implemented as a blocking capacitor and/or in any other suitable manner.

Feedback loop 130 may include a demodulator 131, an amplifier 132, a notch filter 133, an integrator 134, a digital-to-analog converter (DAC) 135, and a summation element 136. The feedback generator 140 may include a current source 141, a coil driver 142, and a reference coil 143.

The operation of signal path 110 is now described in further detail. In operation, the driver circuit 101 and the Hall elements 102 may receive a biasing signal 181. The biasing signal 181 may be either a voltage signal (e.g., a biasing voltage) or a current signal (e.g., a biasing current). The driver circuit 101 may generate a signal 182 to drive the Hall elements 102 based on the biasing signal 181. In some implementations, the level of signal 182 (e.g., voltage or current level) may be proportional to the level of signal 181. In this regard, the signal 181 may specify, at least in part, the amount of power that is delivered from driver circuit 101 to Hall elements 102, which in turn affects the sensitivity of Hall elements 102.

. The signal 182 may be modulated, at frequency FCHOP, by the modulator 108. Hall elements 102 may sense a magnetic field and generate a sensing signal 161 in response. Demodulator 103 may demodulate the sensing signal 161 at the frequency FCHOP to produce a signal 162. Amplifier 104 may amplify signal 162 to produce a signal 163. The LPF 105 may filter the signal 163 to produce a signal 164. The notch filter 106 may filter the signal 164 to remove the harmonics of FCHOP and generate a signal 165. The amplifier 107 may amplify the signal 165 to produce a signal 183. In the present example, signal 183 constitutes the output of signal path 110.

The operation of the signal path 120 is now described in further detail. In operation, the driver circuit 121 and the Hall elements 122 may receive the biasing signal 181. The biasing signal 181 may be either a voltage signal (e.g., a biasing voltage) or a current signal (e.g., a biasing current). The driver circuit 121 may generate a signal 184 to drive the Hall elements 122. Signal 184 may be generated based on the biasing signal 181. In some implementations, the level of signal 184 (e.g., voltage or current level) may be proportional to the level of signal 181. In this regard, biasing signal 181 may specify, at least in part, the amount of power that is delivered from driver circuit 121 to Hall elements 122, which in turn affects the sensitivity of Hall elements 122. In other words, under the nomenclature of the present disclosure, the phrase “adjusting the respective biases of Hall elements 102 and 122 refers to an arrangement whereby the level of biasing signal 181 is adjusted, which in turn affects the power (e.g., voltage and/or current level) that is supplied to each of Hall elements 102 and Hall elements 122.

Hall elements 102 may sense a magnetic field and generate a sensing signal 166, in response. HPF 123 may filter the sensing signal 166 to generate a signal 167. Amplifier 124 may amplify the signal 167 to generate an amplified signal 184. In the present example, signal 184 constitutes the output of signal path 120.

The operation of the reference generator 140 is now described in further detail. In operation, the current source 141 may power the coil driver 142, as shown. The coil driver 142 may drive the reference coil 143 with a signal that has a frequency FMFF. As a result, the coil may generate a reference magnetic field that has the frequency FMFF. The reference magnetic field may be one of the magnetic fields sensed by Hall elements 122 and 102, and it may at least in part be used as a basis for generating the sensing signals 161 and 166. As is discussed further below, the frequency reference magnetic field is used to generate the biasing (feedback) signal 181—specifically, the signal 181 is generated by demodulating the output of Hall elements 122 at the frequency FMFF of the reference magnetic field. As can be readily appreciated, the purpose of the reference magnetic field is to stabilize the sensitivity of Hall elements 122 and 102, over environmental operating conditions. Further information about the use of magnetic reference to stabilize the sensitivity of Hall elements can be found in U.S. patent application Ser. No. 18/152,189, which is herein incorporated by reference in its entirety.

The operation of the feedback loop 130 is now described in further detail. In operation, demodulator 131 may demodulate the signal 166 at the frequency FMFF to produce a demodulated signal 168. The amplifier 132 may amplify the signal 168 to produce a signal 169. The notch filter 133 may filter the signal 169 to remove the harmonics of the frequency FMFF and produce a signal 170. The integrator 134 may integrate the value of signal 170 to produce a signal 171. The period over which integrator 134 integrates the value of signal 170 may be application dependent. In some implementations, the period may be approximately equal to 1 second or half second. However, the present disclosure is not limited to any specific length for the period. DAC 135 may convert signal 171 to produce signal 172. The summation element 136 may generate the biasing signal 181 by subtracting signal 172 from a baseline bias signal VBIAS.

According to the example of FIG. 1A, signal path 110 is used to sense magnetic field signals below a frequency threshold T (e.g., 100 KHz) and the signal path 120 is used to sense magnetic field signals that are above the frequency threshold T. The output signal 183 of the low-frequency signal path 110 is combined with the output signal 184 of the high-frequency signal path 120 by a crossover circuit 160 (hereinafter “crossover 160”). The crossover 160 may produce an output signal 169 based on the signals 183 and 184, and provide the output signal 169 to external circuitry that is coupled to sensor 100. The output signal 169 may be indicative of the level of a magnetic field of interest that is being measured with sensor 100. By way of example, the output signal 169 may also be indicative of the level of an electrical current through a conductor, the speed of a target, the position of a target, and/or any other suitable quantity that is normally measured by using magnetic field sensors.

A comparison is now provided between the respective configurations of signal path 110 and signal path 120. Signal paths 110 and 120 are similar in that they both use Hall elements. However, signal path 110 differs from signal path 120 in that signal path 110 may use one or more offset stabilization techniques that remove offset from the output of Hall elements 102 while also reducing the bandwidth of signal path 110, whereas signal path 120 does not use such offset stabilization techniques that reduce the offset of signal path 120. According to the example of FIG. 1A, signal path 110 uses frequency chopping, whereas signal path 120 purposely does not use frequency chopping. The frequency chopping is performed by modulator 108, demodulator 103, and notch fitter 106. The frequency chopping involves using modulator 108 to alternate the direction of the current (or signal) that is used to drive the Hall elements 102 at the frequency FCHOP, which has the effect of modulating the output of Hall elements 102 (i.e., signal 161). Afterwards, the output of Hall elements 102 is demodulated back to baseband by demodulator 103, which has the effect of removing any offset that is present in signal 161. The notch filter 106 is then applied to remove any residual harmonics of the frequency FCHOP. Under the nomenclature of the present disclosure, the terms “frequency chopping” and “current spinning are used interchangeably.

FIG. 1B shows a curve 151 which represents the frequency response of signal path 110 (i.e., the frequency response of signal 183), and a curve 152 which represents the frequency response of signal path 120 (i.e., the frequency response of signal 184). Also shown in FIG. 1B is the value of threshold T, which represents the cut-off frequency of HPF 123. The dashed portions of curves 152 and 151 may represent the frequency components that are being filtered by HPF 123 and LPF 105. Although, in the present example, the dashed portions are filtered in some implementations they may be left unfiltered. Because FIG. 1B features a logarithmic scale, the addition of these portions to the sum of signals 183 and 184 may be negligible. In sum, FIG. 1B shows that the frequency response of signal path 120 slumps towards the beginning of the low-frequency range (i.e., the range including frequencies that are lower than threshold T), while the frequency response of signal path 110 lags at the beginning of the high-frequency range (i.e., the range including frequencies that are larger than the threshold T).

In some implementations, signal 169 may be calculated by adding signal 183 to signal 184—in other words, signal 169 may be the sum of signals 183 and 184. FIG. 1C shows the plot of a curve 154, which represents the frequency response of signal 169, when signal 169 is calculated by adding signal 183 to signal 184, without using any further processing. As illustrated, curve 154 includes a notch 191 which results from the slump/lag in signals 183 and 184. Having such a notch in the frequency response of signal 169 is undesirable as it could compromise the accuracy of sensor 100. For this reason, crossover 160 may include a filter 185 which is arranged to rectify the notch. The response of filter 185 is represented by curve 157, which is shown in FIG. 1D. The output of filter 185 (in response to the sum of signals 183 and 184) is represented by curve 159, which is shown in FIG. 1E. FIG. 1E is provided to illustrate that the application of filter 185 to the sum of the outputs of signals paths 110 and 120 may produce a flat response of sensor 100 across the entire range of frequencies of interest for sensor 100. In some respects, FIGS. 1B-E are provided to illustrate an example of a cross-over issue, which is herein referred to as “notching”, and which is manifested in the combination of signal paths 110 and 120 having a non-uniform frequency response. In the example of FIG. 1C, the non-uniformity in the combination of signals 183 and 184 is manifested by notch 191.

The configuration of sensor 100 discussed with respect in FIGS. 1A-E has at least two advantages. In one respect, due to the homogeneous nature of the two parallel signal paths (i.e., signal path 110 and signal path 120), the sensitivity calibration of sensor 100 does not have to be performed individually on each channel (i.e., on each of signal paths 110 and 120), but can be shared for both. Specifically, the sensitivity of the chopped hall elements (i.e., hall elements 102) and the static hall plates (i.e., Hall elements 122) can both be stabilized by means of a feedback loop. Hall elements 102 and 122 in the figure above may be located virtually in the same location of the die of sensor 100 (not shown) so that they are exposed to the same external magnetic field.

In another respect, including an ac-coupled static Hall path (i.e., the signal path 120) in sensor 100 enables the bandwidth of sensor 100 to be extended. Since signal path 120 includes static Hall elements (i.e., Hall elements that are not current-spun or frequency-chopped) the magnetic response of signal path 120 is significantly extended over frequency compared to the chopped or current-spun signal path of sensor 100 (i.e., the signal path 110).

The HPF 123 of signal path 120 determines the cut-off frequency at which the signal from signal path 120 (i.e., signal 184) starts to kick in. On the other hand, signal path 110 may be configured such that its cutoff frequency is equal to or otherwise matches the cut-off frequency of signal path 120 (i.e., the cutoff frequency of HPF 123). The notch filter 106 may remove fully (or partially) any modulated offset that is present in signal path 110. The notch characteristics of notch filter 106 would be completely masked by the output of signal path 120, since, at such frequencies, the gain of signal path 110 would be significantly smaller than the gain of signal path 120.

In the example of FIG. 1A, signal 166 is generated by Hall elements 122 at least in response to an external magnetic field and a reference magnetic field. Similarly, signal 161 may also be generated by Hall elements 102 in response to the external magentic field and the reference magnetic field. The external magnetic field may be a field that is desired to be measured by sensor 100, such as a magentic field associated with a moving target or a magnetic field associated with electrical current flowing through a conductor. The reference magnetic field may be generated by reference coil 143.

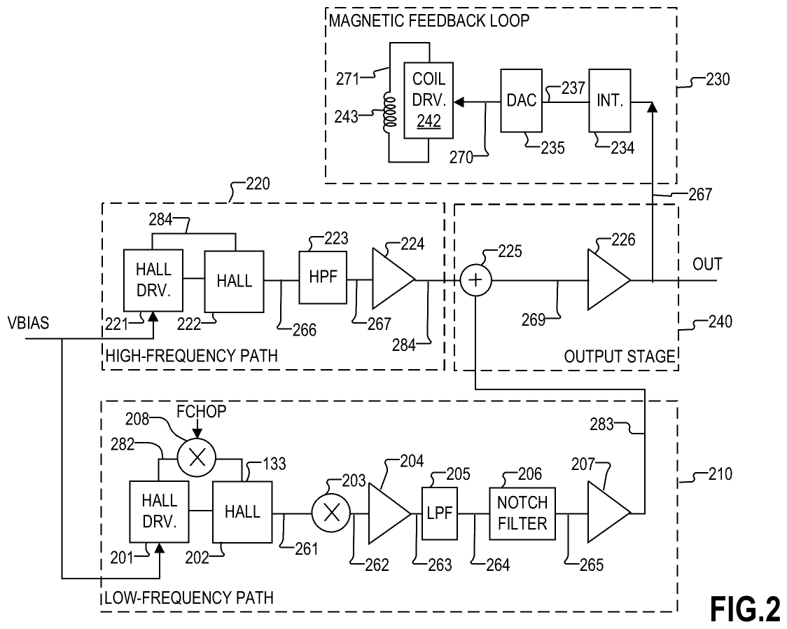

FIG. 2 is a diagram of a magnetic field sensor 200, according to aspects of the disclosure. Sensor 200 may include a position sensor, a current sensor, a speed sensor, and/or any other suitable type of magnetic field sensor. According to the present disclosure, sensor 200 includes a low-frequency signal path 210 (hereinafter “signal path 210”), a high-frequency signal path 220 (hereinafter “signal path 220”), a magnetic feedback loop 230 (hereinafter “feedback loop 230”), an output stage 240. Signal path 210 may include a driver circuit 201, one or more Hall elements 202, a modulator 208, a demodulator 203, an amplifier 204, a low-pass filter (LPF) 205, a notch filter 206, and an amplifier 207. Signal path 220 may include a driver circuit 221, one or more Hall elements 222, a high-pass filter (HPF) 223, and an amplifier 224. Feedback loop 230 may include an integrator 234, a DAC 235, a coil driver 242, and a feedback coil 243. The output stage 240 may include a summation circuit 225, and an amplifier 226. According to the present example, Hall elements 202 and 222 include planar Hall elements. However, alternative implementations are possible in which any of Hall elements 102 and 122 one or more vertical Hall elements and/or any other suitable type of Hall element. The HPF 223 may be implemented as a blocking capacitor and/or in any other suitable manner. The HPF is intended to block the DC offset components generated by the Hall element 222, which is purposely not chopped since it is intended to provide a high frequency response.

The operation of signal path 210 is now described in further detail. In operation, the Hall driver 201 and the Hall elements 202 may receive a baseline biasing signal VBIAS. According to the present example, the biasing signal is a voltage signal, however, alternative implementations are possible in which the biasing signal is a current signal. The driver circuit 201 may generate a signal 282 based on signal VBIAS to drive the Hall elements 202. The signal 282 may be modulated, at frequency FCHOP, by the modulator 208. Hall elements 202 may sense a magnetic field and generate a sensing signal 261 in response. Demodulator 203 may demodulate the sensing signal 261 at the frequency FCHOP to produce a signal 262. Amplifier 204 may amplify signal 262 to produce a signal 263. The LPF 205 may filter the signal 263 to produce a signal 264. The notch filter 206 may filter the signal 264 to remove the harmonics of FCHOP and generate a signal 265. The amplifier 207 may amplify the signal 265 to produce a signal 283. In the present example, signal 283 constitutes the output of signal path 210.

The operation of the signal path 220 is now described in further detail. In operation, the driver circuit 221 and the Hall elements 222 may receive the biasing signal VBIAS. The driver circuit 221 may generate a signal 284 based on the signal VBIAS to drive the Hall elements 222. Hall elements 222 may sense a magnetic field and generate a sensing signal 266, in response. HPF 223 may filter the sensing signal 166 to generate a signal 167. Amplifier 224 may amplify the signal 267 to generate an amplified signal 284. In the present example, signal 284 constitutes the output of signal path 220.

The operation of the output stage 240 is now described in further detail. Summation circuit 225 may receive signals 283 and 284. Summation circuit 225 may add signals 283 and 284 to produce a signal 269. Amplifier 226 may amplify signal 269 to produce a signal 267. According to the present example, signal 267 constitutes the output of sensor 200. By way of example, signal 267 may also be indicative of the level of an electrical current through a conductor, the speed of a target, the position of a target, and/or any other suitable quantity that is normally measured by using magnetic field sensors.

The operation of the feedback loop 230 is now described in further detail. Integrator 234 may receive the signal 267. Integrator 234 may integrate the signal 267 to produce a signal 237. DAC 235 may convert signal 237 to analog signal 270. The analog signal 270 is subsequently supplied to the coil driver 242. The coil driver 242 may generate a signal 271 based on the signal 270. The amperage of signal 271 may be proportional to the voltage level (or value) of signal 270. As can be readily appreciated, the magnitude of the reference magnetic field generated by feedback coil 243 may be proportional to the current level of signal 271. The period over which integrator 234 integrates the value of signal 267 may be application dependent. In some implementations, the period may be approximately equal to 1 second or half second. However, the present disclosure is not limited to any specific length for the period.

The feedback coil 243 may be positioned in such a way that the reference magnetic field (which is generated by it) is sensed by each of Hall elements 202 and Hall elements 222. In some implementations, the feedback coil 243 may be so configured that the magnetic flux density of the reference magnetic field at the location of Hall elements 222 is substantially the same as the magnetic flux density of the magnetic field at the location of Hall elements 202. According to the present disclosure, two magnetic flux densities are “substantially the same” when their magnitudes are within +/−10 percent of each other.

The feedback coil 243 may be configured to stabilize the sensitivity of Hall elements 202 and 222. Furthermore, the feedback coil 243 may be configured to remove any notching that would otherwise be present in the sum of the outputs of signal paths 110 and 120 (e.g., notching in signal 269). As a result of the feedback loop 230 being provided in sensor 200, the frequency response of the signal 267 (e.g., the output signal of sensor 200) is maintained substantially flat, resulting in a seamless combination of the respective outputs of signal paths 210.

In the example of FIG. 2, signal 266 is generated by Hall elements 222 at least in response to an external magnetic field and a reference magnetic field. Similarly, signal 261 may also be generated by Hall elements 202 in response to the external magentic field and the reference magnetic field. The external magnetic field may be a field that is desired to be measured by sensor 200, such as a magentic field associated with a moving target or a magnetic field associated with electrical current flowing through a conductor. The reference magnetic field may be generated by feeback coil 243. In the example of FIG. 2, the reference magnetic field is a feedback field.

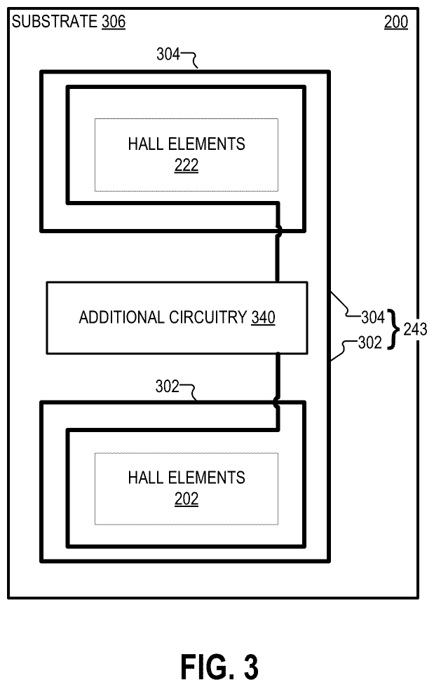

FIG. 3 is a schematic diagram of one possible implementation of sensor 200, according to aspects of the disclosure. In the example of FIG. 3, sensor 200 includes a substrate 306. Formed on the substrate are the feedback coil 243, Hall elements 202, Hall elements 222, and additional circuitry 340. Additional circuitry 340 may include all components of sensor 200 that are shown in FIG. 2, other than feedback coil 243, and the Hall elements 202 and 222. The substrate 306 may include a silicon substrate and/or any suitable type of substrate. The coil portions 302 and 304 may be implemented as conductive traces formed on the substrate 306. Each coil portion 302 and 304 may be regarded as a separate coil. Both coil portions 302 and 304 may be driven with the same current (e.g., signal 271). According to the present example, coil portions 302 and 304 are identical—e.g., they include the same number of turns and have the same physical dimensions. However, alternative implementations are possible in which coil portions 302 and 304 are different—for example, they may include a different number of turns or have different physical dimensions. Although, in the present example, coil portions 302 and 304 are configured to surround Hall elements 202 and 222, respectively, alternative implementations are possible in which coil portion 302 is disposed to the side of Hall elements 202 and/or coil portion 304 is disposed to the side of Hall elements 222. Although, in the present example, feedback coil 234 is divided into two coil portions, alternative implementations are possible in which feedback coil 234 is implemented as a monolithic coil. Furthermore, although in the present example, feedback coil 234 is provided on the sensor die, alternative implementations are possible in which feedback coil is provided separately from the packaging of sensor 200, such as on an auxiliary printed circuit board. Stated succinctly, the present disclosure is not limited to any specific implementation of the feedback coil 243.

A magnetic-field sensing element can be, but is not limited to, a Hall Effect element a magnetoresistance element, or an inductive coil. As is known, there are different types of Hall Effect elements, for example, a vertical Hall element, and a Circular Vertical Hall (CVH) element. As is also known, there are different types of magnetoresistance elements, for example, a semiconductor magnetoresistance element such as Indium Antimonide (InSb), a giant magnetoresistance (GMR) element, an anisotropic magnetoresistance element (AMR), a tunneling magnetoresistance (TMR) element, and a magnetic tunnel junction (MTJ). The magnetic field sensing element may be a single element or, alternatively, may include two or more magnetic field sensing elements arranged in various configurations, e.g., a half bridge or full (Wheatstone) bridge. Depending on the device type and other application requirements, the magnetic field sensing element may be a device made of a type IV semiconductor material such as Silicon (Si) or Germanium (Ge), or a type III-V semiconductor material like Gallium-Arsenide (GaAs) or an Indium compound, e.g., Indium-Antimonide (InSb). The phrase “set of magnetic field elements” shall mean “one or more magnetic field sensing elements”.

The concepts and ideas described herein may be implemented, at least in part, via a computer program product, (e.g., in a non-transitory machine-readable storage medium such as, for example, a non-transitory computer-readable medium), for execution by, or to control the operation of, data processing apparatus (e.g., a programmable processor, a computer, or multiple computers). Each such program may be implemented in a high-level procedural or object-oriented programming language to work with the rest of the computer-based system. However, the programs may be implemented in assembly, machine language, or Hardware Description Language. The language may be a compiled or an interpreted language, and it may be deployed in any form, including as a stand-alone program or as a module, component, subroutine, or another unit suitable for use in a computing environment. A computer program may be deployed to be executed on one computer or multiple computers at one site or distributed across multiple sites and interconnected by a communication network. A computer program may be stored on a non-transitory machine-readable medium that is readable by a general or special-purpose programmable computer for configuring and operating the computer when the non-transitory machine-readable medium is read by the computer to perform the processes described herein. For example, the processes described herein may also be implemented as a non-transitory machine-readable storage medium, configured with a computer program, where upon execution, instructions in the computer program cause the computer to operate in accordance with the processes. A non-transitory machine-readable medium may include but is not limited to a hard drive, compact disc, flash memory, non-volatile memory, or volatile memory. The term unit (e.g., an addition unit, a multiplication unit, etc.), as used throughout the disclosure may refer to hardware (e.g., an electronic circuit) that is configured to perform a function (e.g., addition or multiplication, etc.), software that is executed by at least one processor, and configured to perform the function, or a combination of hardware and software.

Also, for purposes of this description, the terms “couple,” “coupling,” “coupled,” “connect,” “connecting,” or “connected” refer to any manner known in the art or later developed in which energy is allowed to be transferred between two or more elements, and the interposition of one or more additional elements is contemplated, although not required. Conversely, the terms “directly coupled,” “directly connected,” etc., imply the absence of such additional elements. Like reference numerals refer to like elements.

As used herein in reference to an element and a standard, the term “compatible” means that the element communicates with other elements in a manner wholly or partially specified by the standard, and would be recognized by other elements as sufficiently capable of communicating with the other elements in the manner specified by the standard. The compatible element does not need to operate internally in a manner specified by the standard.

Having described preferred embodiments, which serve to illustrate various concepts, structures and techniques, which are the subject of this patent, it will now become apparent that other embodiments incorporating these concepts, structures and techniques may be used. Accordingly, it is submitted that the scope of the patent should not be limited to the described embodiments but rather should be limited only by the spirit and scope of the following claims.

1. A sensor, comprising:
a first signal path including one or more first Hall elements that are configured to generate a first signal in response to an external magnetic field that is incident on the sensor and a reference magnetic field, the first signal path further including a first electronic circuitry that is configured to process the first signal to generate a first processed signal;
a second signal path including one or more second Hall elements that are configured to generate a second signal in response to the external magnetic field and the reference magnetic field, the second signal path further including a second electronic circuitry that is configured to process the second signal to generate a second processed signal;
a reference coil that is configured to generate the reference magnetic field, the reference magnetic field having a reference magnetic field frequency;
a feedback circuit that is configured to: receive the first signal, demodulate the first signal at the reference magnetic field frequency to generate a demodulated signal, integrate the demodulated signal to produce an integrated signal, and use the integrated signal to adjust respective biases of the first Hall elements and the second Hall elements; and
a combination circuit that is configured to combine the first signal and the second signal to produce an output signal, the output signal being generated at least in part based on the first signal and the second signal.

2. The sensor of claim 1, wherein the second signal path uses frequency chopping to remove offset from the second signal and the first signal path does use frequency chopping to remove offset from first signal.

3. The sensor of claim 1, wherein the first signal path includes a first driver circuit that is arranged to drive the first Hall elements and the second signal path includes a second driver circuit that is arranged to drive the second Hall elements, wherein the feedback circuit is configured adjust respective biases of the first driver circuit and the second driver circuit.

4. The sensor of claim 1, wherein the first electronic circuitry includes a high-pass filter that is arranged to filter the first signal to generate a first filtered signal, the first processed signal being generated based on the first filtered signal.

5. The sensor of claim 1, wherein the second electronic circuitry includes a modulator that is configured to modulate a signal used to drive the second Hall elements at a chopping frequency, a demodulator that is arranged to demodulate the second signal to produce a second demodulated signal, and a low-pass filter that is configured to filter the second demodulated signal to produce a second filtered signal, the second processed signal being generated based on the second filtered signal.

6. The sensor of claim 5, wherein the second electronic circuitry includes a notching filter that is configured to remove harmonics of the chopping frequency.

7. The sensor of claim 1, wherein the first Hall elements and the second Hall elements include vertical Hall elements.

8. The sensor of claim 1 wherein the first Hall elements and the second Hall elements include planar Hall elements.

9. The sensor of claim 1, wherein adjusting the respective biases of the first and second Hall elements includes adjusting the amount of power that is supplied to the first and second Hall elements.

10. The sensor of claim 1, wherein the output signal is indicative of at least one of position of a target, speed of a target, or a level of electrical current through a conductor.

11. A sensor, comprising:
a first signal path including one or more first Hall elements that are configured to generate a first signal in response to an external magnetic field that is incident on the sensor and a reference magnetic field, the first signal path further including a first electronic circuitry that is configured to process the first signal to generate a first processed signal;
a second signal path including one or more second Hall elements that are configured to generate a second signal in response to the external magnetic field and the feedback magnetic field, the second signal path further including a second electronic circuitry that is configured to process the second signal to generate a second processed signal;
a summation element configured to add the first processed signal to the second processed signal to generate an output signal of the sensor; and
a feedback circuit including an integrator, a feedback coil configured to generate the reference magnetic field, a feedback coil driver, and an integrator, the integrator being configured to integrate the output signal to generate an integrated signal, the feedback coil driver being configured to drive the feedback coil with a drive current that is generated at least in part based on the integrated signal.

12. The sensor of claim 11, wherein the second signal path uses frequency chopping to remove offset from the second signal and the first signal path does use frequency chopping to remove offset from first signal.

13. The sensor of claim 11, wherein the feedback coil includes a first portion and a second portion that is coupled in series to the first portion, the first portion being disposed adjacent to the first Hall elements and the second portion being disposed adjacent to the second Hall elements.

14. The sensor of claim 11, wherein the feedback coil includes a first portion and a second portion that is coupled in series to the first portion, the first portion being arranged to surround the first Hall elements and the second portion being arranged to surround the second Hall elements.

15. The sensor of claim 11, wherein the first electronic circuitry includes a high-pass filter that is arranged to filter the first signal to generate a first filtered signal, the first processed signal being generated based on the first filtered signal.

16. The sensor of claim 11, wherein the second electronic circuitry includes a modulator that is configured to modulate a signal used to drive the second Hall elements at a chopping frequency, a demodulator that is arranged to demodulate the second signal to produce a second demodulated signal, and a low-pass filter that is configured to filter the second demodulated signal to produce a second filtered signal, the second processed signal being generated based on the second filtered signal.

17. The sensor of claim 16, wherein the second electronic circuitry includes a notching filter that is configured to remove harmonics of the chopping frequency.

18. The sensor of claim 11, wherein the first Hall elements and the second Hall elements include vertical Hall elements.

19. The sensor of claim 11 wherein the first Hall elements and the second Hall elements include planar Hall elements.

20. The sensor of claim 11, wherein the output signal is indicative of at least one of position of a target, speed of a target, or a level of electrical current through a conductor.
